(19) United States
(12) Patent Application Publication
(10) Pub. No.: US 2024/0039245 A1
(43) Pub. Date: Feb. 1, 2024

(54) OPTOELECTRONIC DEVICE

(71) Applicant: ams-OSRAM International GmbH, Regensburg (DE)

(72) Inventor: Fabian KNORR, Postbauer-Heng (DE)

(73) Assignee: ams-OSRAM International GmbH, Regensburg (DE)

(21) Appl. No.: 18/257,033

(22) PCT Filed: Dec. 2, 2021
(86) PCT No.: PCT/EP2021/083895

§ 371 Date: Jun. 12, 2023

(30) Foreign Application Priority Data
Dec. 15, 2020 (DE) 10 2020 133 504.0

(51) Int. Cl. H01S 5/183; H01L 27/15; H01S 5/42

(52) U.S. Cl. CPC H01S 5/18386; H01L 27/153; H01S 5/423

(57) ABSTRACT

The invention relates to an optoelectronic device having at least two emission regions and having a radiation exit face, the emission regions each having an active region provided to generate radiation, the active regions of the emission regions being arranged in a common emitter plane. The emission regions are each assigned a portion of the radiation exit face through which portion the radiation emitted by the respective emission region exits, wherein the radiation exit face is formed at least in part by a radiation-permeable body which is arranged on at least one of the emission regions, and wherein the portions of the radiation exit face are arranged at differing distances from the common emitter plane.

### CROSS-REFERENCE TO RELATED APPLICATIONS

The present application is a national stage entry from International Application No. PCT/EP2021/083895, filed on Dec. 2, 2021, published as International Publication No. WO 2022/128496 A1 on Jun. 23, 2022, and claims priority to German Patent Application No. 10 2020 133 504.0, filed Dec. 15, 2020, the disclosures of all of which are hereby incorporated by reference in their entireties.

### FIELD OF THE INVENTION

The present application relates to an optoelectronic device.

### BACKGROUND OF THE INVENTION

For various applications, optoelectronic devices are desired in which multiple emission regions are provided that have different virtual focal points from each other. This may be achieved, for example, by placing different surface emitters at different levels in a package, for example by using intermediate carriers.

However, this increases the manufacturing effort and can only be realized with comparatively low precision.

One object is to specify an optoelectronic device that can be easily and reliably manufactured and is characterized by emission regions with different focal points.

This object is solved, inter alia, by an optoelectronic device according to claim 1. Further embodiments and expediencies are the subject of the dependent claims.

### SUMMARY OF THE INVENTION

An optoelectronic device having at least two emission regions and having a radiation exit surface is specified. The optoelectronic device may have exactly two emission regions or even more than two emission regions. The radiation exit surface forms in particular a transition to a surrounding medium, for example a gas, such as air. The emission regions may in particular be controlled independently of one another.

According to at least one embodiment of the optoelectronic device, the emission regions each have an active region provided for generating radiation. The active region is provided, for example, for generating radiation in the infrared, visible or ultraviolet spectral range. In particular, the active regions may be nominally of the same type. Thus, the emission regions emit radiation with a wavelength of maximum emission that does not differ or differs only slightly among the active regions. For example, the wavelengths of maximum emission between the emission regions differ from each other by at most 20 nm or at most 10 nm or at most 5 nm. In particular, the active regions are controllable independently of one another.

According to at least one embodiment of the optoelectronic device, the active regions of the emission regions are arranged in a common emitter plane. The common emitter plane indicates in particular the vertical position of the active regions. The active regions of the emission regions are thus not offset from one another in a vertical direction, i.e. perpendicular to a main extension plane of the active regions, or at least at most within the scope of manufacturing tolerances in the placement of the emission regions.

According to at least one embodiment of the optoelectronic device, the emission regions are each assigned a partial region of the radiation exit surface through which the radiation emitted by the respective emission region exits. The partial regions each run parallel to the common emitter plane, for example.

According to at least one embodiment of the optoelectronic device, the radiation exit surface is formed at least in places by a radiation-transmissive body. Radiation-transmissive means in this context in particular that the radiation-transmissive body transmits the radiation generated during operation of the optoelectronic device with the wavelength of maximum emission. For example, the radiation-transmissive body has a transmission of at least 80% or at least 90% or at least 95% for this wavelength.

The radiation-transmissive body is arranged on at least one of the emission regions and, in particular, is fastened thereto. Between the radiation-transmissive body and the front side of the emission region facing the radiation-transmissive body, there is preferably at most one bonding layer for fastening the radiation-transmissive body to the emission region. In particular, there is no gap between the radiation-transmissive body and the emission region, for example in the form of an air gap.

For example, the radiation-transmissive body comprises a glass, a plastic, or a semiconductor material that is transmissive to the radiation with the wavelength of maximum emission. For example, a refractive index of the radiation-transmissive body differs by at least 0.1 from a refractive index of the surrounding medium. For example, the refractive index of the radiation-transmissive body is between 1.1, inclusive, and the average refractive index of the active regions, inclusive. When in doubt, the refractive index refers to the refractive index at the wavelength of maximum emission at room temperature.

For example, the radiation-transmissive body has a front side forming the radiation exit surface and an opposite back side extending parallel thereto. In the simplest case, the radiation-transmissive body is formed in one piece. Deviating from this, the radiation-transmissive body may also be provided with a coating, for example an anti-reflective coating.

According to at least one embodiment of the optoelectronic device, the partial regions of the radiation exit surface are arranged at different distances from each other with respect to the common emitter plane. Via the different distances it can be achieved that the optical path lengths of the radiation generated in the emission regions differ from each other from the emission regions to a plane parallel to the emitter plane outside the optoelectronic device. For example, the partial regions of the radiation exit surface are vertically offset from each other, each of which is parallel to the common emitter plane.

In at least one embodiment of the optoelectronic device, the optoelectronic device comprises at least two emission regions and a radiation exit surface, the emission regions each comprising an active region provided for generating radiation. The active regions of the emission regions are arranged in a common emitter plane, wherein a partial region is assigned to each of the emission regions as a radiation exit surface through which the radiation emitted by the respective emission region exits. The radiation exit surface is formed at least in places by a radiation-transmissive body which is arranged on at least one of the emission regions and, in particular, is fastened thereto. The partial regions of the radiation exit surface are arranged at mutually different distances from the common emitter plane.

By means of the radiation-transmissive body, it can be achieved that the virtual focal points for the two emission regions differ from each other, even if the emission regions are arranged in a common emitter plane and have the same spatial radiation characteristic. The distance between the virtual focal points of the emission regions can be adjusted with high precision via the optical path length through the radiation-transmissive body and, in particular, adapted to a given application of the optoelectronic device.

According to at least one embodiment of the optoelectronic device, the virtual focal points of the emission regions differ from each other in their distance from the associated active regions. In particular, the virtual focal points of the emission regions may also be different from each other, although the emission regions per se have the same spatial radiation characteristic and the same position of the active regions in the vertical direction. By controlling the active regions separately, it is possible, for example, to switch between two different illumination areas without the need for mechanically moving parts.

According to at least one embodiment of the optoelectronic device, radiation cones of the emitted radiation emerging from the partial regions of the radiation exit surface overlap during operation of the optoelectronic device. For example, the radiation cones overlap at a distance of 20 cm from the common emitter plane by at least 80% or by at least 90% or by at least 95%.

According to at least one embodiment of the optoelectronic device, during operation of the optoelectronic device, the radiation emitted by one emission region only emerges from exactly one partial region of the radiation exit surface. Thus, one emission region illuminates only one partial region of the radiation exit surface in each case.

According to at least one embodiment of the optoelectronic device, the radiation-transmissive body has a front side forming the partial region radiation exit surface, and a thickness of the radiation-transmissive body perpendicular to the front side is at most such that the radiation cone exiting the associated emission region exits completely from the front side of the radiation-transmissive body. Complete radiation exit here refers to a direct beam path of the radiation cone using geometric optics. Thus, no radiation emerges through side surfaces of the radiation-transmissive body that connect the front side and the back side of the radiation-transmissive body, or at most radiation that impinges on the side surfaces after a scattering or a back reflection at the radiation exit surface.

According to at least one embodiment of the optoelectronic device, one of the emission regions is free of the radiation-transmissive body. In this region, the radiation exit surface may be formed by a front side of the emission region, for example by a surface of a semiconductor device forming the emission region.

According to at least one embodiment of the optoelectronic device, the radiation-transmissive body is arranged on one of the emission regions and a further radiation-transmissive body is arranged on the other emission region. Here, the radiation-transmissive body and the further radiation-transmissive body differ from each other in their optical path length.

In this way, it can be achieved that the radiation coupling out from both emission regions does not occur directly to the surrounding medium, but via the radiation-transmissive bodies. The distance between the virtual focal points of the emission regions can be adjusted via the different optical path lengths through the radiation-transmissive body and the further radiation-transmissive body. For example, the radiation-transmissive body and the further radiation-transmissive body are formed of the same material, so that the distance of the virtual focal points is adjustable via the difference in thickness of the two radiation-transmissive bodies. Alternatively or complementarily, the radiation-transmissive bodies may differ from each other in refractive index, for example by using different materials.

According to at least one embodiment of the optoelectronic device, the radiation-transmissive body is a prefabricated element attached to the associated emission region. For example, the radiation-transmissive body is attached to the associated emission region by means of a bonding layer, such as an adhesive layer. Alternatively, the radiation-transmissive body may be attached directly to the associated emission region without a bonding layer, for example by direct bonding or anodic bonding.

If appropriate, this may apply analogously to the further radiation-transmissive body.

As an alternative to a further radiation-transmissive body, the partial regions of the radiation exit surface may also be formed by a common radiation-transmissive body, in which, for example, the front side is step-shaped.

According to at least one embodiment of the optoelectronic device, the active region of at least one emission region is subdivided into a plurality of individual emitters. In particular, both emission regions may also be subdivided into a plurality of individual emitters, respectively. For example, the individual emitters are arranged next to each other in a row-like or matrix-like manner. For example, the number of individual emitters per emission region is between 10 and 1000 inclusive. For example, the individual emitters are arranged with a density between 50/mm² and 1000/mm² inclusive. For example, an edge length of the individual emitters is between 2 μm and 2 mm, inclusive.

According to at least one embodiment of the optoelectronic device, the number of individual emitters in one emission region differs from one another by at most 10% between the emission regions. In particular, the number of individual emitters for the emission regions may also be the same. Deviating from this, however, the number of individual emitters may also differ from each other by more than 10%.

According to at least one embodiment of the optoelectronic device, the individual emitters of one emission region are integrated into a common semiconductor body. In particular, the individual emitters of one emission region may emerge from a common semiconductor layer sequence during manufacture. The individual emitters therefore do not differ from each other with regard to the layer structure of the active region or at most within the scope of manufacturing-related variations.

According to at least one embodiment of the optoelectronic device, the emission regions are integrated into a common semiconductor body. The emission regions may thus be arranged particularly close to each other. In this case, therefore, at least two partial regions of the radiation exit surface overlap with the common semiconductor body as seen along the vertical direction. For example, the optoelectronic device has exactly one semiconductor body which forms all emission regions, in particular with several individual emitters in each case.

According to at least one embodiment of the optoelectronic device, the emission regions are each formed by surface emitters. In contrast to a volume emitter, the radiation in a surface emitter emerges predominantly, for example to at least 60%, to at least 80% or to at least 90%, through a surface running parallel to the active region. In contrast, radiation coupling out through side faces running obliquely or perpendicularly to the active region is minimized.

For example, the surface emitters are surface emitting light emitting diodes or surface emitting semiconductor lasers.

According to at least one embodiment of the optoelectronic device, the emission regions are each formed by a matrix of vertical cavity surface emitting semiconductor lasers (VCSELs). Such surface emitting semiconductor lasers can emit radiation with high intensity and luminance directionally.

For example, a plurality of individual emitters is formed by a monolithically integrated matrix of VCSELs. For example, the individual emitters emerge from a common semiconductor layer sequence during fabrication. One, several or even all of the individual emitters may further be associated with a radiation conversion element, which is configured to convert a primary radiation emitted by the active region completely or at least partially into a secondary radiation.

The described optoelectronic device is suitable, for example, as a radiation source for three-dimensional sensing applications, time of flight (TOF) measurements, illumination applications, for example, headlight applications, or projection applications, and combinations thereof.

### BRIEF DESCRIPTION OF THE DRAWING

Further embodiments and expediencies will be apparent from the following description of the exemplary embodiments in conjunction with the figures.

In the Figures:

FIG. 1A shows a schematic sectional view of an exemplary embodiment of an optoelectronic device;

FIGS. 1B and 1C show schematic representations illustrating criteria for radiation exit through a radiation-transmissive body;

FIG. 2 shows an exemplary embodiment of an emission region for an optoelectronic device in schematic sectional view; and

FIG. 3 shows a further exemplary embodiment of an optoelectronic device in schematic sectional view.

### DETAILED DESCRIPTION

Identical, similar or similarly acting elements are given the same reference signs in the figures.

The figures are each schematic representations and therefore not necessarily true to scale. Rather, comparatively small elements and, in particular, layer thicknesses may be shown exaggeratedly large for improved representation and/or better understanding.

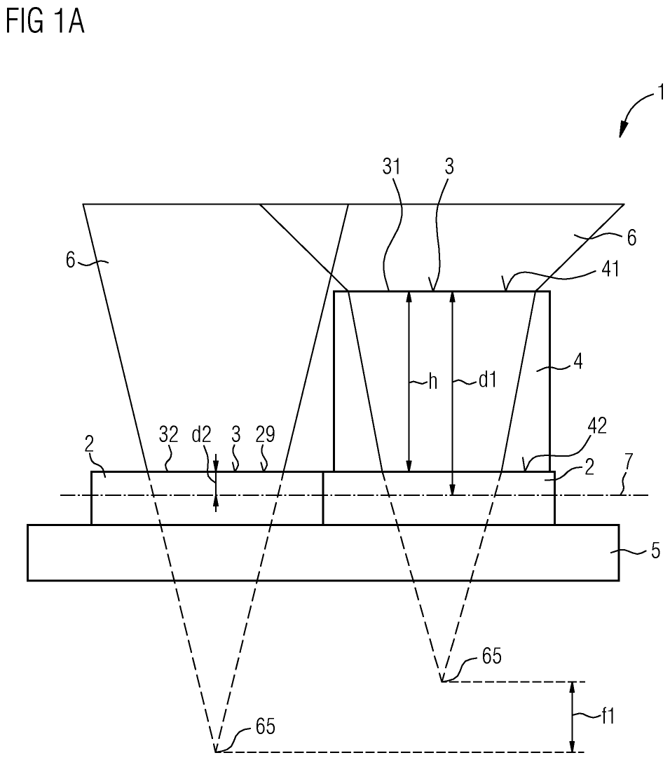

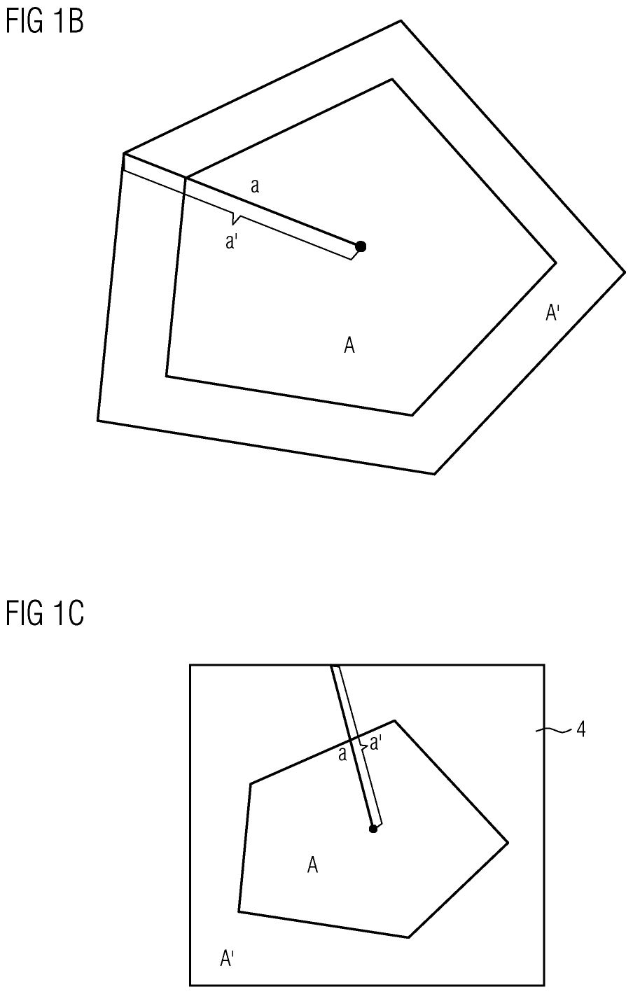

The optoelectronic device 1 according to the exemplary embodiment shown in FIG. 1A comprises two emission regions 2 and a radiation exit surface 3. The emission regions 2 each have an active region 20 provided for generating radiation (compare FIG. 2). The active regions 20 are arranged in a common emitter plane 7. A first partial region 31 and a second partial region 32 of the radiation exit surface 3 are assigned to the emission regions 2, respectively. During operation of the optoelectronic device 1, the radiation emitted by the respectively assigned emission region 2 exits the optoelectronic device 1 into the surrounding medium through these partial regions 31, 32, respectively. The surrounding medium is, for example, a gas, such as air. Alternatively, however, the surrounding medium may also be an encapsulation material, for example.

The first partial region 31 of the radiation exit surface 3 is formed by a radiation-transmissive body 4. The radiation-transmissive body 4 extends in the vertical direction between a back side 42 facing the associated emission region 2 and an opposite front side 41, which forms a partial region, for example the first partial region 31, of the radiation exit surface 3.

The first partial region 31 and the second partial region 32 each extend parallel to the common emitter plane 7, wherein a distance d1 of the first partial region 31 from the common emitter plane 7 is different from a second distance d2 between the second partial region 32 and the common emitter plane 7. The different distances of the partial regions 31, 32 of the radiation exit surface 3 from the common emitter plane 7 result in virtual focal points 65 of the emission regions 2, which differ from their distance to their associated active regions 20, so that there is a vertical distance f1 between the virtual focal points 65 in the vertical direction. The optoelectronic device 1 thus provides two emission regions 2, the emission regions 2 differing from each other with respect to the vertical distance of the virtual focal points 65 from the common emitter plane 7. For this purpose, the emission regions 2 may be of the same type and need not differ from each other with respect to their spatial radiation characteristics. Furthermore, the emission regions 2 may be arranged next to each other on a carrier 5 without having to increase the distance of the active region from the carrier 5 for one of the emission regions 2, for example by using an intermediate carrier. The carrier may be, for example, a printed circuit board or part of a housing.

During operation of the optoelectronic device 1, the radiation cones 6 of the emitted radiation emerging from the first partial region 31 and the second partial region 32 of the radiation exit surface 3 overlap. In particular, the radiation cones may overlap by at least 70%, at least 80% or at least 90%. The radiation emitted by an emission region 2 emerges in each case from exactly one partial region 31, 32 of the radiation exit surface 3. In particular, the radiation emerges only from partial regions of the radiation exit surface 3 that run parallel to the common emitter plane 7.

Preferably, the thickness of the radiation-transmissive body 4 perpendicular to the front side 41 is at most such that the radiation cone 6 emerging from the associated emission region 2 exits completely from the front side of the radiation-transmissive body 4.

The maximum thickness of the radiation-transmissive body 4 according to this criterion can be derived using geometric considerations in conjunction with radiation parameters of the emission regions. This is illustrated in FIGS. 1B and 1C. The considerations assume a radiation emission with a maximum divergence angle with respect to the normal to the front side of 151, where the spectral emission extends between a lower emission wavelength λ₁ and an upper emission wavelength λ₂. The refractive index for the lower emission wavelength λ₁ of the radiation-transmissive body 4 is denoted as n₁.

At the front side 29 of the emission regions 2, intersections of these edge rays with the front side 29 form a closed bordered area A. This results in a closed bordered area A′ in a plane A′ parallel to it, the shape of which is mathematically similar to the border A with a scaling factor s>0.

For a ray passing through the geometric center C of the surface A, which meets the boundary of the surface A after a projected length a, a corresponding projected length a′ for the boundary of the surface A′ results with a′=r*a, where r is a factor >1.

If the front side 41 of the radiation-transmissive body 4 is considered as area A′, the longest projected length a′ must lie within the front side. This results in the following condition for the maximum thickness of the radiation-transmissive body

h≤(a′−a)/tan(ϑ₁/(2*n₁))

The maximum vertical distance f1 of the virtual focal points 65 then results from the height h of the radiation-transmissive body 4 multiplied by its refractive index for the emitted radiation.

The radiation-transmissive body 4 has, for example, a thickness of at least 100 μm. A radiation-transmissive body 4 with such a thickness can be transferred to the corresponding emission region 2 in a simplified manner when manufacturing the optoelectronic device 1.

For example, a glass, such as a quartz glass or a plastic, is suitable for the radiation-transmissive body 4.

Alternatively, a semiconductor material whose band gap is larger than the energy of the emitted radiation with the wavelength of maximum emission of the radiation emitted by the optoelectronic device may also be used.

The radiation-transmissive body 4 is a prefabricated element attached to the associated emission region 2. For example, the radiation-transmissive body 4 may be attached to the emission region 2 with a bonding layer, such as an adhesive layer. For example, a bonding layer based on a polymer material, such as a silicone or an epoxy, is suitable.

Alternatively, the attachment of the radiation-transmissive body 4 to the associated emission region 2 may be accomplished without a bonding layer, for example by direct bonding or anodic bonding.

A distance between the front side 29 of the emission region 2 and the radiation-transmissive body 4 is determined by the thickness of the adhesive layer, if present, and is, for example, at most 50 μm or at most 20 μm. In the case of a joint without a bonding layer, the distance may also be 0.

In the exemplary embodiment shown in FIG. 1A, one of the emission regions 2 is free of the radiation-transmissive body 4. For this emission region 2, a front side 29 of the emission region 2 forms the second partial region 32 of the radiation exit surface 3.

An exemplary embodiment of an emission region 2 is shown schematically in FIG. 2 in sectional view. The emission region 2 has a plurality of individual emitters 25, which are arranged next to each other in the lateral direction.

In the vertical direction, the active region 20 is arranged between a first semiconductor layer 21 of a first conductivity type and a second semiconductor layer 22 of a second conductivity type different from the first conductivity type, so that the active region 20 is located in a pn junction. For example, the first semiconductor layer 21 is n-type and the second semiconductor layer 22 is p-type, or vice versa. The individual emitters 25 are each partial regions of a semiconductor body formed by the semiconductor layers 20, 21, 22, which is arranged on a substrate 23. The substrate 23 may be the growth substrate for the semiconductor layer sequence or a substrate different from the growth substrate.

The first semiconductor layer 21, the active region 20, and the second semiconductor layer 22 may each be formed in multiple layers. For example, the active region may have a quantum structure with a plurality of quantum wells. Preferably, at least the individual emitters 25 of an emission region 2 are integrated in a common semiconductor body. In this way, particularly small distances between the individual emitters 25 may be achieved. Furthermore, the active regions 20 may also be arranged in vertical direction between two resonator mirrors. The resonator mirrors may be formed at least in part by semiconductor layers of the semiconductor body or by layers arranged outside the semiconductor body. This is not explicitly shown for simplified illustration.

Furthermore, both emission regions 2 or more than two emission regions 2 may also be integrated into a common semiconductor body. In this way, the distances between adjacent emission regions 2 may be minimized, for example in comparison to two emission regions 2, which are each formed by separate semiconductor bodies and need to be placed next to each other when mounting on the carrier 5.

The emission regions 2 may each be surface emitters, for example surface emitters in the form of light emitting diodes or in the form of laser diodes, in particular in unhoused form. For example, the emission regions 2 are each formed by a matrix of vertical cavity surface emitting semiconductor lasers.

For example, the active regions 20 are based on a III-V compound semiconductor material.

III-V compound semiconductor materials are particularly suitable for radiation generation in the ultraviolet (Alₓ In_{y} Gal_{1-x-y} N) through the visible (Alₓ In_{y} Ga_{1-x-y} N, in particular for blue to green radiation, or Alₓ In_{y} Ga_{1-x-y} P, in particular for yellow to red radiation) to the infrared (Alₓ In_{y} Gal_{1-x-y} As) spectral range. Here, 0≤x≤1, 0≤y≤1 and x+y≤1, respectively, especially with x≠1, y≠1, x≠0 and/or y≠0. III-V compound semiconductor materials, especially those made of the aforementioned material systems, may further be used to achieve high internal quantum efficiencies in radiation generation.

In particular, the active regions 20 may be nominally of the same design, so that the wavelengths of maximum emission for the emission regions 2 do not differ from one another, or at most differ within manufacturing tolerances.

For example, the number of individual emitters 25 of an emission region 2 is between 10 and 1000 inclusive. The number of individual emitters may be varied within wide limits and may also be correspondingly smaller or larger. For example, a density of the individual emitters is between 50 and 1000 per mm² inclusive.

The number of individual emitters 25 per emission region 2 may, for example, be the same or differ only slightly from each other. This allows the optoelectronic device 1 to have two emission regions 2 that provide the same optical output power and differ only in the vertical position of the virtual focal point 65. In principle, however, the number of individual emitters in the emission regions 2 may also be different. Furthermore, the optoelectronic device 1 can, of course, also have more than two emission regions 2, with two or more emission regions 2 differing from one another with respect to the distances of their virtual focal points 65 from the respective associated active regions.

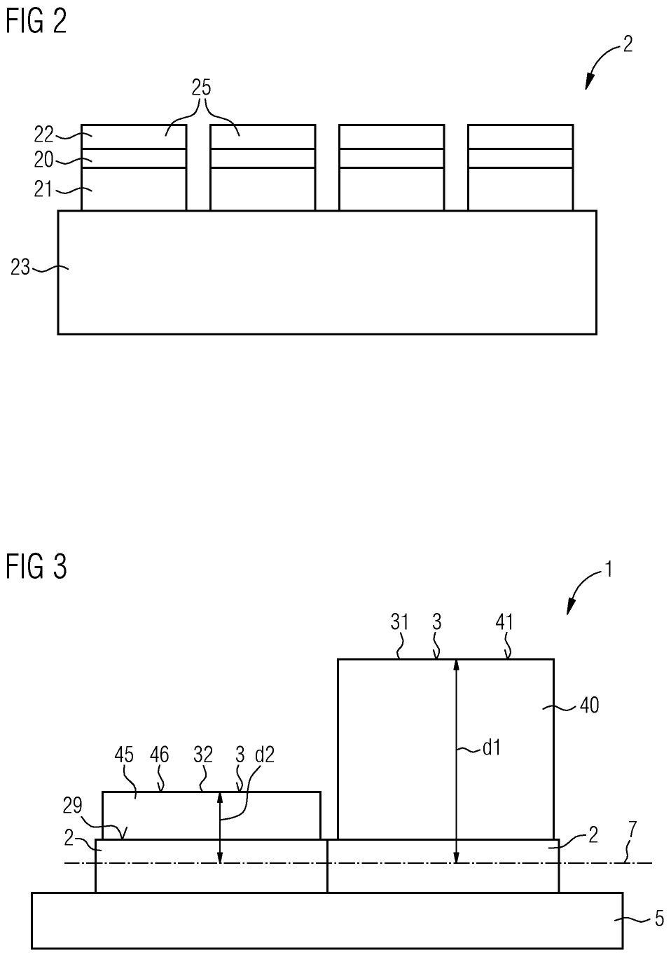

The exemplary embodiment illustrated in FIG. 3 is essentially the same as the exemplary embodiment described in connection with FIG. 1A.

In contrast, the radiation-transmissive body 4 is arranged on one of the emission regions 2 and a further radiation-transmissive body 45 is arranged on the other emission region 2. The radiation-transmissive body 4 and the further radiation-transmissive body 45 differ from each other in their thickness, i.e. in their extension in vertical direction. The vertical distance f1 between the virtual focal points 65 can be adjusted via the difference in thickness and/or via different refractive indices (compare FIG. 1A).

A front side 46 of the further radiation-transmissive body 45 thus forms the second partial region 32 of the radiation exit surface 3. In this exemplary embodiment, the radiation coupling out from both emission regions 2 does not take place directly into the surrounding medium, but in each case via a radiation-transmissive body, namely the radiation-transmissive body 4 on the one hand and the further radiation-transmissive body 45 on the other hand. Efficient radiation coupling out for both emission regions 2 is thus simplified.

Deviating from the illustrated exemplary embodiment, the first partial region 31 and the second partial region 32 of the radiation exit surface 3 may also be formed by a common radiation-transmissive body 4, which covers the two emission regions 2. For this purpose, the radiation-transmissive body 4 may have, for example, a step-shaped front side 41. In this way, the number of radiation-transmissive bodies 4 to be placed per optoelectronic device 1 may be reduced. On the other hand, the effort for the production of the radiation-transmissive body 4 increases due to the required formation of partial regions with different thicknesses.

By the described configuration of the optoelectronic device 1 with at least one radiation-transmissive body 4, an optoelectronic device 1 with at least two emission regions 2 may be provided in a simple and reliable manner, wherein the emission regions 2 differ from one another in particular only with respect to the distance of their virtual focal point from the common emitter plane 7. The required thickness of the radiation-transmissive body 4 may be reliably set and adapted to the desired application by simple processes, for example a mechanical process such as grinding, lapping or polishing.

The invention is not limited by the description based on the exemplary embodiments. Rather, the invention encompasses any new feature as well as any combination of features, which in particular includes any combination of features in the patent claims, even if this feature or combination itself is not explicitly stated in the claims or the exemplary embodiments.

1. An optoelectronic device with at least two emission regions and with a radiation exit surface, wherein
the emission regions each comprise an active region provided for generating radiation,
the active regions of the emission regions are arranged in a common emitter plane,
the emission regions are each assigned a partial region of the radiation exit surface through which the radiation emitted by the respective emission region exits,
the radiation exit surface is formed at least in places by a radiation-transmissive body arranged on at least one of the emission regions, and
the partial regions of the radiation exit surface are arranged at different distances from each other with respect to the common emitter plane.

2. The optoelectronic device according to claim 1,
wherein the virtual focal points of the emission regions differ in their distance from the associated active regions.

3. The optoelectronic device according to claim 1,
wherein, during operation of the optoelectronic device, radiation cones of the emitted radiation emerging from the partial regions of the radiation exit surface overlap.

4. The optoelectronic device according to claim 1,
wherein, during operation of the optoelectronic device, the radiation emitted by an emission region emerges in each case from only exactly one partial region of the radiation exit surface.

5. The optoelectronic device according to claim 1,
wherein the radiation-transmissive body has a front side which forms the partial region of the radiation exit surface, and a thickness of the radiation-transmissive body perpendicular to the front side is at most such that the radiation cone exiting from the associated emission region exits completely from the front side of the radiation-transmissive body.

6. The optoelectronic device according to claim 1,
wherein one of the emission regions is free of the radiation-transmissive body.

7. The optoelectronic device according to claim 1,
wherein the radiation-transmissive body is arranged on one of the emission regions and a further radiation-transmissive body is arranged on the other emission region, wherein the radiation-transmissive body and the further radiation-transmissive body differ from each other in their thickness.

8. The optoelectronic device according to claim 1,
wherein the radiation-transmissive body is a prefabricated element attached to the associated emission region.

9. The optoelectronic device according to claim 1,
wherein the active region of at least one emission region is divided into a plurality of individual emitters.

10. The optoelectronic device according to claim 9,
wherein the number of individual emitters in an emission region differs from one another by at most 10% between the emission regions.

11. The optoelectronic device according to claim 9,
wherein the individual emitters of one emission region are integrated in a common semiconductor body.

12. The optoelectronic device according to claim 1,
wherein the emission regions are integrated into a common semiconductor body.

13. The optoelectronic device according to claim 1,
wherein the emission regions are each formed by surface emitters.

14. The optoelectronic device according to claim 1,
wherein the emission regions are each formed by a matrix of vertical cavity surface emitting semiconductor lasers.

15. An optoelectronic device with at least two emission regions and with a radiation exit surface, wherein
the at least two emission regions each comprise an active region provided for generating radiation,
the active regions of the at least two emission regions are arranged in a common emitter plane,
the at least two emission regions are each assigned a partial region of a radiation exit surface through which the radiation emitted by the respective emission region exits,
the radiation exit surface is formed at least in places by a radiation-transmissive body arranged on at least one of the emission regions,
the partial regions of the radiation exit surface are arranged at different distances from each other with respect to the common emitter plane,
the partial regions each run parallel to the common emitter plane, and
the active region of at least one emission region is divided into a plurality of individual emitters.
